(19) United States
(12) Patent Application Publication
(10) Pub. No.: US 2026/0223287 A1
(43) Pub. Date: Jul. 30, 2026

(54) WIRING BOARD

(71) Applicant: SHINKO ELECTRIC INDUSTRIES CO., LTD., Nagano (JP)

(72) Inventor: Keigo SATO, Nagano (JP)

(21) Appl. No.: 19/454,747

(22) Filed: Jan. 21, 2026

(30) Foreign Application Priority Data
Jan. 29, 2025 (JP) 2025-012736

(51) Int. Cl. H05K 1/02; H05K 1/11

(52) U.S. Cl. CPC H05K 1/0298; H05K 1/115

(57) ABSTRACT

A wiring board includes a stack, a recess that opens at an upper surface and a side surface of the stack, a metal layer having an upper surface exposed at a bottom of the recess, and an insulating layer having an upper surface exposed at the bottom of the recess. A side surface of the metal layer is covered with the insulating layer.

### CROSS-REFERENCE TO RELATED APPLICATIONS

This application is based upon and claims priority to Japanese Patent Application No. 2025-012736, filed on Jan. 29, 2025, the entire contents of which are incorporated herein by reference.

### FIELD

Certain aspects of the embodiments discussed herein are related to wiring boards, and methods for manufacturing wiring boards.

### BACKGROUND

A known wiring board includes a core layer, and a stack of alternately stacked interconnect layers and insulating layers provided on the core layer. In such a wiring board, a recess may be formed by removing a portion of the stack. The recess is open at an upper surface and a side surface of the stack, for example, and a metal layer is exposed at a bottom of the recess. Such a wiring board is proposed in Japanese Laid-Open Patent Publication No. 2022-162487, for example.

During manufacturing processes of the wiring board, a structure including the core layer and the stack is made, and a routing process or the like is performed on the stack to form the recess having the metal layer exposed at the bottom of the recess, for example. Thereafter, unnecessary portions of the structure are cut and removed so as to divide the recess, to obtain the wiring board. When cutting and removing the unnecessary portions, burrs may be generated on a side surface of the metal layer if a large portion of the metal layer is cut.

### SUMMARY

It is an object in one aspect of the embodiments of the present disclosure to provide a wiring board having a structure designed to minimize burrs on a side surface of a metal layer exposed at a bottom portion of a recess.

According to one aspect of the embodiments of the present disclosure, a wiring board includes a stack; a recess that opens at an upper surface and a side surface of the stack; a metal layer having an upper surface exposed at a bottom of the recess; and an insulating layer having an upper surface exposed at the bottom of the recess, wherein a side surface of the metal layer is covered with the insulating layer.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a plan view illustrating an example of a wiring board according to a first embodiment;

FIG. 2A and FIG. 2B are cross sectional views illustrating the example of the wiring board according to the first embodiment;

FIG. 3 is a first diagram illustrating an example of a manufacturing process of the wiring board according to the first embodiment;

FIG. 4A, FIG. 4B, FIG. 4C, and FIG. 4D are second diagrams illustrating examples of the manufacturing processes of the wiring board according to the first embodiment;

FIG. 5A, FIG. 5B, and FIG. 5C are third diagrams illustrating examples of the manufacturing processes of the wiring board according to the first embodiment;

FIG. 6A, FIG. 6B, and FIG. 6C are fourth diagrams illustrating examples of the manufacturing processes of the wiring board according to the first embodiment;

FIG. 7 is a fifth diagram illustrating examples of the manufacturing processes of the wiring board according to the first embodiment;

FIG. 8A and FIG. 8B are diagrams illustrating an example of the wiring board according to a first modification of the first embodiment;

FIG. 9 is a plan view illustrating an example of the wiring board according to a second modification of the first embodiment;

FIG. 10A and FIG. 10B are cross sectional views illustrating an example of the wiring board according to a third modification of the first embodiment;

FIG. 11A and FIG. 11B are cross sectional views illustrating an example of the wiring board according to a fourth modification of the first embodiment;

FIG. 12 is a partial cross sectional view illustrating an example of the wiring board according to a fifth modification of the first embodiment; and

FIG. 13 is a cross sectional view illustrating an example of an optical module according to a second embodiment.

### DESCRIPTION OF EMBODIMENTS

Hereinafter, embodiments of the present disclosure will be described with reference to the drawings. In the drawings, the same constituent elements or components are designated by the same reference numerals, and a redundant description thereof may be omitted.

### First Embodiment

### Structure of Wiring Board

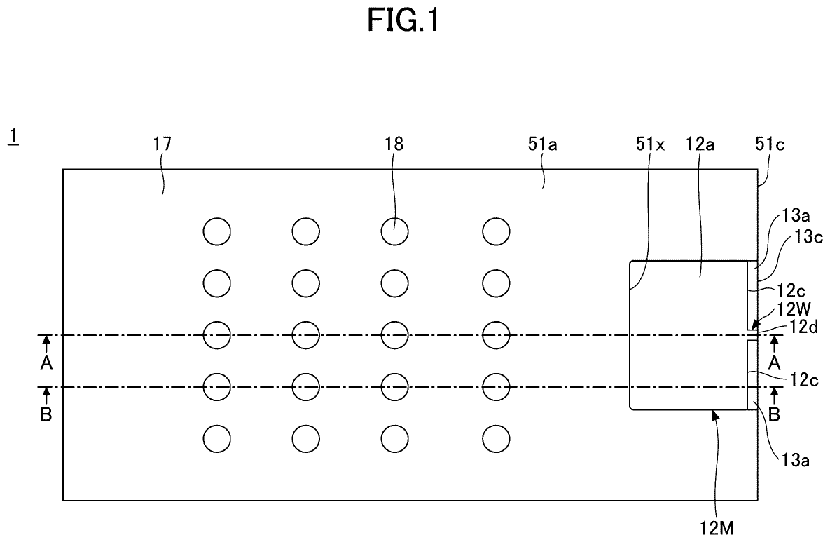

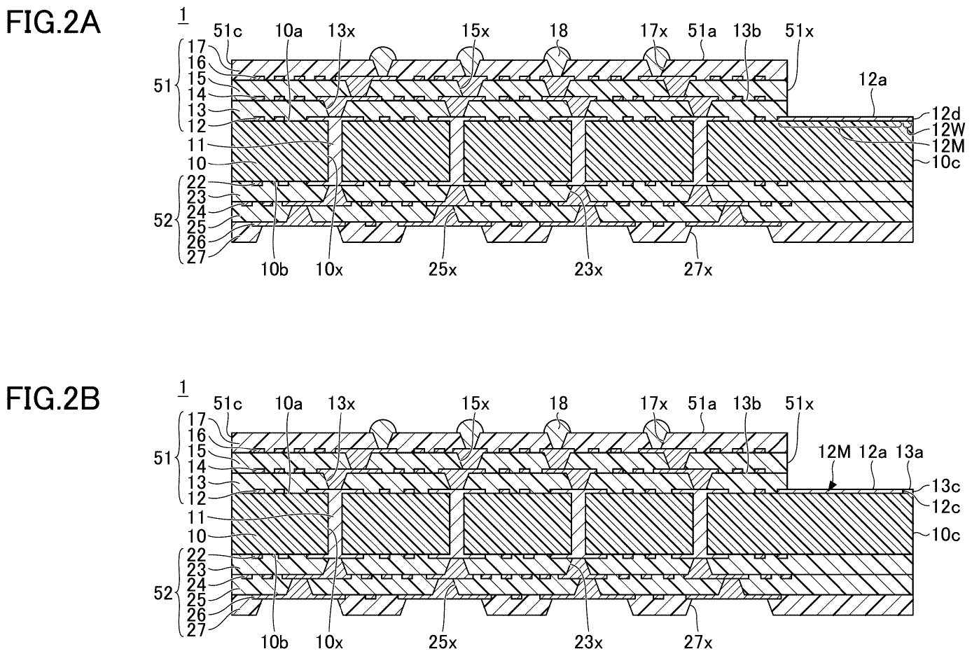

FIG. 1 is a plan view illustrating an example of a wiring board according to a first embodiment. FIG. 2A and FIG. 2B are cross sectional views illustrating the example of the wiring board according to the first embodiment, where FIG. 2A is a cross sectional view taken along a line A-A in FIG. 1, and FIG. 2B is a cross sectional view taken along a line B-B in FIG. 1.

As illustrated in FIG. 1, FIG. 2A, and FIG. 2B, a wiring board 1 includes a core layer 10 having a first surface 10a and a second surface 10b opposite from the first surface 10a, a first stack 51 (or a first multilayer structure) that includes interconnect layers and insulating layers alternately stacked on the first surface 10a of the core layer 10, a second stack (or a second multilayer structure) 52 including interconnect layers and insulating layers alternately stacked on the second surface 10b of the core layer 10, and a recess 51x opening at an upper surface 51a and a side surface 51c of the first stack 51. The wiring board 1 may include an external connection terminal 18. The wiring board 1 may be formed in a rectangular shape in a plan view, for example.

The first stack 51 includes an interconnect layer 12, an insulating layer 13, an interconnect layer 14, an insulating layer 15, an interconnect layer 16, and a solder resist layer 17, which are sequentially stacked on the first surface 10a of the core layer 10. The second stack 52 includes an interconnect layer 22, an insulating layer 23, an interconnect layer 24, an insulating layer 25, an interconnect layer 26, and a solder resist layer 27 that are sequentially stacked on the second surface 10b of the core layer 10.

For the sake of convenience, in the first embodiment, the side of the wiring board 1 provided with the solder resist layer 17 is referred to as an upper side or one side, and the side of the wiring board 1 provided with the solder resist layer 27 is referred to as a lower side or the other side. Further, a surface of each portion on the side of the wiring board 1 provided with solder resist layer 17 is referred to as one surface or an upper surface of each portion, and a surface of each portion on the side of the wiring board 1 provided with the solder resist layer 27 is referred to as the other surface or a lower surface of each portion. However, the wiring board 1 may be used in an upside-down state or may be used in a state disposed at an arbitrary angle. Further, a plan view of an object refers to a view of the object viewed from above in a normal direction to the first surface 10a of the core layer 10, and a planar shape of the object refers to a shape of the object in the plan view viewed from above in the normal direction to the first surface 10a of the core layer 10.

The core layer 10 may be formed to have a rectangular shape in the plan view, for example. For example, a so-called glass epoxy substrate or the like in which glass cloth is impregnated with an insulating resin, such as an epoxy-based resin or the like, can be used for the core layer 10. A substrate or the like in which a woven fabric or a nonwoven fabric of glass fiber, carbon fiber, aramid fiber, or the like is impregnated with an epoxy-based resin or the like may be used for the core layer 10. Glass or silicon may also be used for the core layer 10. In a case where glass is used for the core layer 10, the type of glass is not particularly limited, and for example, alkali-free glass, quartz glass, borosilicate glass, or the like can be used.

A thickness of the core layer 10 is in a range of approximately 100 μm to approximately 1000 μm, for example. The core layer 10 has through holes 10x penetrating the core layer 10 in a thickness direction. The planar shape of the through hole 10x is a circular shape, for example. A diameter of the through hole 10x may be 100 μm or greater and 500 μm or less, for example.

The interconnect layer 12 is disposed on the first surface 10a of the core layer 10. The interconnect layer 22 is disposed on the second surface 10b of the core layer 10. The interconnect layer 12 and the interconnect layer 22 are electrically connected to each other via through-hole vias 11 formed in the through holes 10x. The interconnect layers 12 and 22 are patterned into predetermined planar shapes. The interconnect layers 12 and 22 and the through-hole vias 11 may be made of copper (Cu) or the like, for example. Thicknesses of the interconnect layers 12 and 22 are in a range of approximately 10 μm to approximately 40 μm, for example. The interconnect layer 12, the interconnect layer 22, and the through-hole vias 11 may be integrally formed. The interconnect layer 12 may include a metal layer 12M having an upper surface 12a and a side surface 12c, and an interconnect 12W having an end surface 12d.

The insulating layer 13 is an interlayer dielectric that is disposed on the first surface 10a of the core layer 10 and covers the interconnect layer 12. Examples of a material used for the insulating layer 13 include an insulating resin or the like including an epoxy-based resin or a polyimide-based resin as a main component, for example. A thickness of the insulating layer 13 may be in a range of approximately 30 μm to approximately 40 μm, for example. The insulating layer 13 may include a filler, such as silica (SiO₂) or the like.

The insulating layer 13 has via holes 13x penetrating the insulating layer 13 and exposing an upper surface of the interconnect layer 12. The via hole 13x may be a cavity having an inverted truncated cone shape such that a diameter (or area) of an opening of the via hole 13x that opens toward the insulating layer 15 is larger than a diameter (or area) of a bottom surface of the via hole 13x formed by the upper surface of the interconnect layer 12.

The interconnect layer 14 is formed on one side of the insulating layer 13. The interconnect layer 14 includes via interconnects filling insides of the via holes 13x, and interconnect patterns formed on an upper surface of the insulating layer 13. The interconnect patterns are electrically connected to the interconnect layer 12 through the via interconnects. The material of the interconnect layer 14 and the thickness of the interconnect pattern may be the same as those of the interconnect layer 12, for example.

The insulating layer 15 is formed on the upper surface of the insulating layer 13 to cover the interconnect layer 14. A material used for and a thickness of the insulating layer 15 may be the same as those of the insulating layer 13, for example. The insulating layer 15 may include a filler, such as silica (SiO₂) or the like.

The insulating layer 15 has via holes 15x penetrating the insulating layer 15 and exposing an upper surface of the interconnect layer 14. The via hole 15x may be a cavity having an inverted truncated cone shape such that a diameter (or area) of an opening of the via hole 15x that opens toward the solder resist layer 17 is larger than a diameter (or area) of a bottom surface of the via hole 15x formed by the upper surface of the interconnect layer 14.

The interconnect layer 16 is formed on one side of the insulating layer 15. The interconnect layer 16 includes via interconnects filling insides of the via holes 15x, and pads formed on an upper surface of the insulating layer 15. The pads are electrically connected to the interconnect layer 14 through the via interconnects. A material used for the interconnect layer 16 and a thickness of the pads may be the same as those of the interconnect layer 12, for example. The thickness of the pad may be greater than the thickness of the interconnect layer 12. The interconnect layer 16 may include interconnect patterns in addition to the pads.

The solder resist layer 17 is a protective insulating layer located at an outermost position on one side of the wiring board 1, and is formed on an upper surface of the insulating layer 15 to cover the interconnect layer 16. The solder resist layer 17 has openings 17x, and portions of an upper surface of the interconnect layer 16 are exposed inside the openings 17x, respectively. A planar shape of the opening 17x may be a circular shape, for example. The interconnect layer 16 exposed inside the openings 17x may be used as pads for electrical connection with an electronic component, such as a semiconductor chip or the like, for example. The solder resist layer 17 may be formed of a photosensitive epoxy-based insulating resin or a photosensitive acrylic-based insulating resin, for example. A thickness of the solder resist layer 17 is in a range of approximately 15 μm to approximately 35 μm, for example.

A metal layer may be formed on the surface of the interconnect layer 16 exposed inside the openings 17x of the solder resist layer 17, or an organic coating or film may be formed on the surface of the interconnect layer 16 exposed inside the openings 17x of the solder resist layer 17 by performing an anti-oxidation treatment, such as an organic solderability preservative (OSP) treatment or the like. Examples of the metal layer include a gold (Au) layer, a nickel/gold (Ni/Au) layer (a metal layer in which a Ni layer and a Au layer are stacked in this order), a nickel/palladium/gold (Ni/Pd/Au) layer (a metal layer in which a Ni layer, a Pd layer, and a Au layer are stacked in this order), a tin (Sn) layer, or the like.

If necessary, external connection terminals 18 may be provided on the interconnect layer 16 exposed inside the openings 17x. The external connection terminals 18 are solder bumps, for example. A material used for the solder bump include an alloy including Pb, an alloy of Sn and Cu, an alloy of Sn and silver (Ag), an alloy of Sn, Ag, and Cu, or the like, for example.

The insulating layer 23 is an interlayer dielectric that is disposed on the second surface 10b of the core layer 10 and covers the interconnect layer 22. A material used for and a thickness of the insulating layer 23 may be the same as those of the insulating layer 13, for example. The insulating layer 23 may include a filler, such as silica (SiO₂) or the like.

The insulating layer 23 has via holes 23x penetrating the insulating layer 23 and exposing a lower surface of the interconnect layer 22. The via holes 23x may be a cavity having a truncated cone shape such that a diameter (or area) of an opening of the via hole 23x that opens toward the insulating layer 25 is larger than a diameter (or area) of a bottom surface of the via hole 23x formed by the lower surface of the interconnect layer 22.

The interconnect layer 24 is formed on the other side of the insulating layer 23. The interconnect layer 24 includes via interconnects filling insides of the via holes 23x, and interconnect patterns formed on a lower surface of the insulating layer 23. The interconnect patterns are electrically connected to the interconnect layer 22 through the via interconnects. A material used for and a thickness of the interconnect layer 24 may be the same as those of the interconnect layer 12, for example.

The insulating layer 25 is formed on the lower surface of the insulating layer 23 to cover the interconnect layer 24. A material used for and a thickness of the insulating layer 25 may be the same as those of the insulating layer 13, for example. The insulating layer 25 may include a filler, such as silica (SiO₂) or the like.

The insulating layer 25 has via holes 25x penetrating the insulating layer 25 and exposing a lower surface of the interconnect layer 24. The via holes 25x may be a cavity having a truncated cone shape such that a diameter (or area) of an opening of the via hole 25x that opens toward the solder resist layer 27 is larger than a diameter (or area) of a bottom surface of the via hole 25x formed by the lower surface of the interconnect layer 24.

The interconnect layer 26 is formed on the other side of the insulating layer 25. The interconnect layer 26 includes via interconnects filling insides of the via holes 25x, and interconnect patterns formed on a lower surface of the insulating layer 25. The interconnect patterns are electrically connected to the interconnect layer 24 through the via interconnects. A material used for and a thickness of the interconnect layer 26 may be the same as those of the interconnect layer 12, for example.

The solder resist layer 27 is a protective insulating layer located at an outermost position on the other side of the wiring board 1, and is formed on the lower surface of the insulating layer 25 to cover the interconnect layer 26. A material used for and a thickness of the solder resist layer 27 may be the same as those of the solder resist layer 17, for example. The solder resist layer 27 includes openings 27x, and portions of a lower surface of the interconnect layer 26 are exposed inside the openings 27x, respectively. A planar shape of the openings 27x may be a circular shape, for example. The interconnect layer 26 exposed inside the openings 27x can be used as pads for electrical connection to a printed circuit board, such as a motherboard or the like. If necessary, a metal layer may be formed on the lower surface of the interconnect layer 26 exposed inside the openings 27x, or an anti-oxidation treatment, such as an OSP treatment or the like, may be performed on the lower surface of the interconnect layer 26 exposed inside the openings 27x.

The recess 51x penetrates the solder resist layer 17 and the insulating layer 15. In addition, the recess 51x is formed to a portion of the insulating layer 13. The metal layer 12M and the insulating layer 13 are exposed at a bottom of the recess 51x. Specifically, the upper surface 12a of the metal layer 12M extending from the first stack 51 and an upper surface 13a of the insulating layer 13 extending from the first stack 51 are exposed at the bottom of the recess 51x. The side surface 12c of the metal layer 12M exposed at the bottom of the recess 51x is located closer to a center of the first stack 51 than to the side surface 51c of the first stack 51 in the plan view. The side surface 12c of the metal layer 12M exposed at the bottom of the recess 51x is parallel to the side surface 51c of the first stack 51 in the plan view, for example. The side surface 12c of the metal layer 12M exposed at the bottom of the recess 51x is covered with the insulating layer 13 exposed at the bottom of the recess 51x. The upper surface 12a of the metal layer 12M exposed at the bottom of the recess 51x can be used as a component mounting surface, for example.

The upper surface 13a of the insulating layer 13 exposed at the bottom of the recess 51x is located at a position lower than an upper surface 13b of the insulating layer 13 constituting the first stack 51. The upper surface 12a of the metal layer 12M lies on the same plane as the upper surface 13a of the insulating layer 13, for example. A side surface 13c of the insulating layer 13 exposed at the bottom of the recess 51x is exposed on the side of a side surface 10c of the core layer 10. In addition, the side surface 13c of the insulating layer 13 exposed at the bottom of the recess 51x is exposed on the side of the side surface 51c of the first stack 51. The side surface 13c of the insulating layer 13 exposed at the bottom of the recess 51x lies on the same plane as the side surface 10c of the core layer 10, for example. Further, the side surface 13c of the insulating layer 13 exposed at the bottom of the recess 51x lies on the same plane as the side surface 51c of the first stack 51, for example.

The recess 51x has a rectangular shape in the plan view, for example. An inner wall surface of the recess 51x is perpendicular to the first surface 10a of the core layer 10. The upper surface 12a of the metal layer 12M and the upper surface 13a of the insulating layer 13, which constitute the bottom surface of the recess 51x, are parallel to the first surface 10a of the core layer 10, for example. In the present specification, the terms “perpendicular” and “parallel” may tolerate a deviation of ±10 degrees from a perfectly perpendicular state and a perfectly parallel state, respectively.

The interconnect 12W is electrically connected to the metal layer 12M. The interconnect 12W may be linear in the plan view, or may include a bent portion or a curved portion. The end surface 12d of the interconnect 12W is exposed on the side of the side surface 10c of the core layer 10. In addition, the end surface 12d of the interconnect 12W is exposed on the side of the side surface 51c of the first stack 51. The end surface 12d of the interconnect 12W lies on the same plane as the side surface 10c of the core layer 10, for example. Further, the end surface 12d of the interconnect 12W lies on the same plane as the side surface 51c of the first stack 51, for example. A thickness of the interconnect 12W is identical to a thickness of the metal layer 12M and a thickness of the insulating layer 13 exposed inside the recess 51x, for example. That is, an upper surface of the interconnect 12W lies on the same plane as the upper surface 12a of the metal layer 12M and the upper surface 13a of the insulating layer 13, for example. In the present embodiment, the interconnect 12W is provided in the same layer as the metal layer 12M and is exposed at the bottom of the recess 51x, but the present disclosure is not limited to such a structure.

For example, if the core layer 10 and the metal layer 12M are to be cut when manufacturing the wiring board 1, burrs may be generated on the side surface 12c of the metal layer 12M, and the burrs may become exposed on the side of the side surface 10c of the core layer 10. In addition, the burrs may become exposed on the side of the side surface 51c of the first stack 51. However, as described later, when manufacturing the wiring board 1, there is no process of cutting the metal layer 12M, and the side surface 12c of the metal layer 12M is covered with the insulating layer 13. That is, the side surface 12c of the metal layer 12M is not exposed on the side of the side surface 10c of the core layer 10 nor on the side of the side surface 51c of the first stack 51. Hence, this structure is designed to minimize burrs generated on the side surface 12c of the metal layer 12M exposed at the bottom of the recess 51x. When the interconnect 12W is cut together with the core layer 10 when manufacturing the wiring board 1, burrs may be formed on the end surface 12d of the interconnect 12W. However, a cutting width of the interconnect 12W is narrow compared to a cutting width of the metal layer 12M, and burrs are less likely generated when cutting the interconnect 12W.

### [Method for Manufacturing Wiring Board]

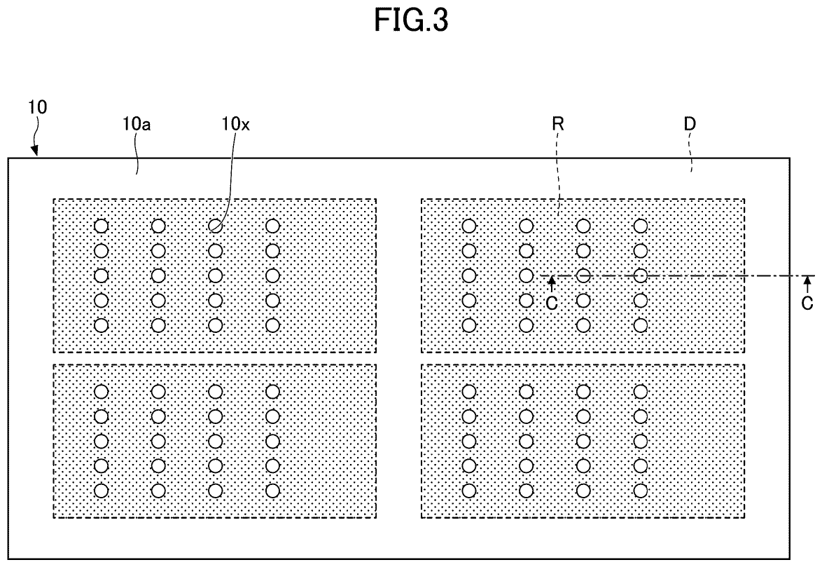

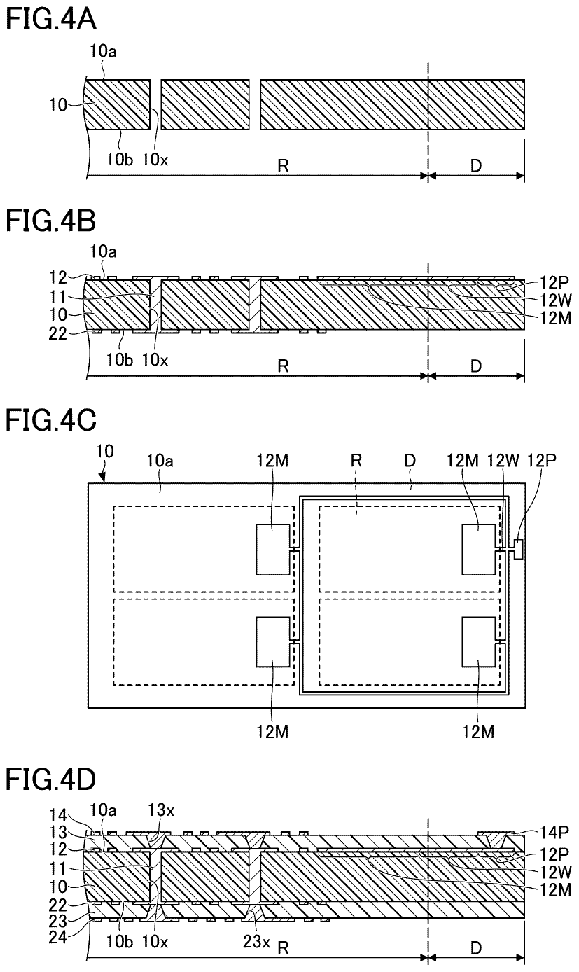

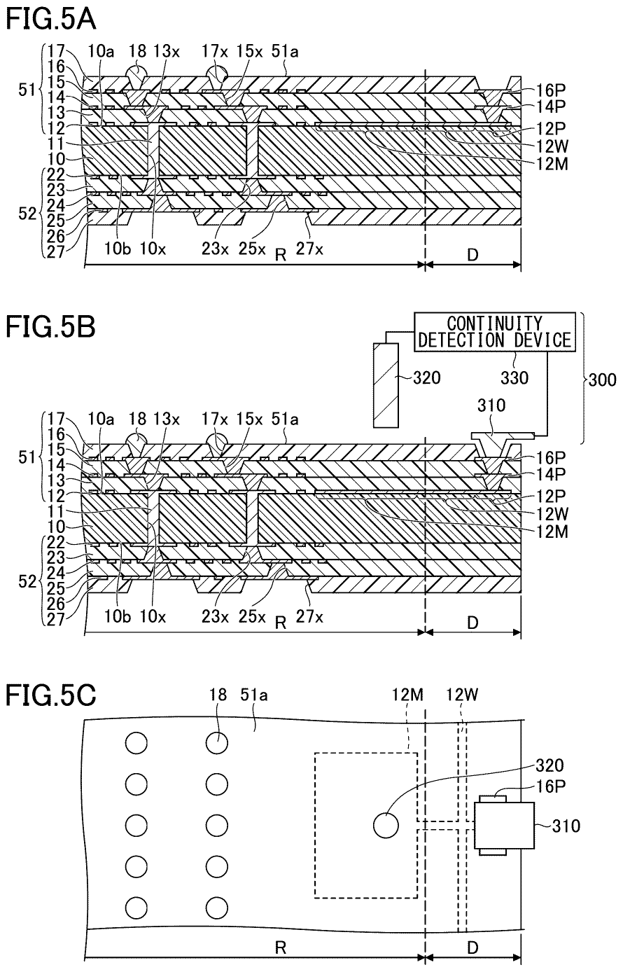

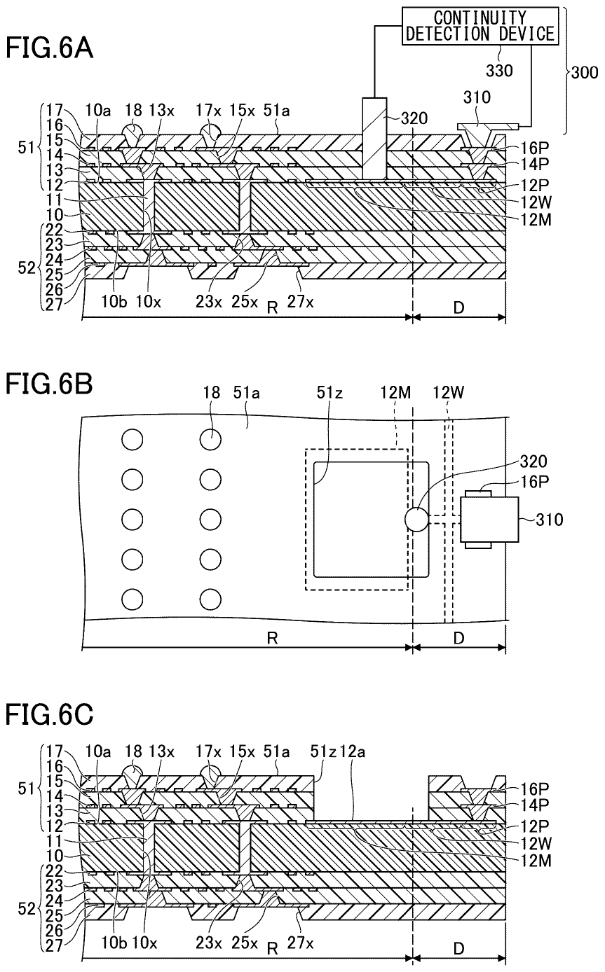

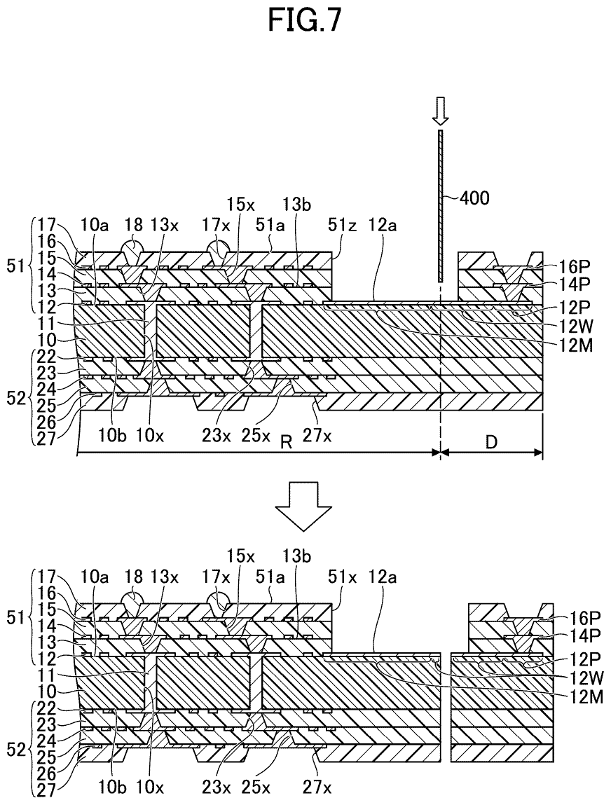

FIG. 3, FIG. 4A, FIG. 4B, FIG. 4C, FIG. 4D, FIG. 5A, FIG. 5B, FIG. 5C, FIG. 6A, FIG. 6B, FIG. 6C, and FIG. 7 are diagrams illustrating examples of manufacturing processes of the wiring board according to the first embodiment. FIG. 3, FIG. 4C, FIG. 5C, and FIG. 6B are plan views. FIG. 4A, FIG. 4B, FIG. 4D, FIG. 5A, FIG. 5B, FIG. 6A, FIG. 6C, and FIG. 7 are partial cross sectional views corresponding to a position of a line C-C in FIG. 3. FIG. 5C and FIG. 6B are partial plan views including the position of the line C-C in FIG. 3.

First, in the processes illustrated in FIG. 3 and FIG. 4A, the core layer 10 is prepared. The core layer 10 includes a plurality of interconnect regions R that become wiring boards when singulated, and a dicing region D to be cut when singulating the core layer 10. Further, the through holes 10x penetrating from the first surface 10a to the second surface 10b of the core layer are formed in the core layer 10 located in the interconnect regions R. The through holes 10x can be formed using laser processing, drilling, wet etching, or the like, for example. In FIG. 3, the interconnect regions R are indicated by dot patterns for the sake of convenience, and all regions without the dot patterns form the dicing region D. The number of interconnect regions R may be one.

Next, in the processes illustrated in FIG. 4B through FIG. 5A, the first stack 51 is formed on the interconnect region R and the dicing region D on the first surface 10a of the core layer 10. In addition, the second stack 52 is formed on the interconnect region R and the dicing region D on the second surface 10b of the core layer 10.

Specifically, as illustrated in FIG. 4B and FIG. 4C, the interconnect layer 12 is disposed on the first surface 10a of the core layer 10, and the interconnect layer 22 is disposed in each interconnect region R on the second surface 10b of the core layer 10. The through-hole vias 11 are formed in the through holes 10x. In each interconnect region R illustrated in FIG. 4C, the illustration of the interconnect layer 12 other than the metal layer 12M and the interconnect 12W is omitted for the sake of convenience.

For example, a seed layer (made of copper or the like) is formed using electroless plating, sputtering, or the like to cover the first surface 10a, the second surface 10b, and inner wall surfaces of the through holes 10x of the core layer 10. In addition, an electrolytic plating layer (made of copper or the like) is formed on the seed layer using electrolytic plating using the seed layer as a power supplying layer (or a current feeding layer). As a result, the through holes 10x are filled with the electrolytic plating layer formed on the seed layer, and a conductive layer in which the seed layer and the electrolytic plating layer are stacked is formed on the first surface 10a and the second surface 10b of the core layer 10. Next, the conductive layer is patterned into predetermined planar shapes using a subtractive process or the like to form the interconnect layers 12 and 22.

The interconnect layer 12 is formed to include the metal layer 12M, the interconnect 12W, and pads 12P. The metal layer 12M is formed in each interconnect region R and does not reach the dicing region D. One pad 12P is formed in the dicing region D. The interconnect 12W is electrically connected to the metal layer 12M in the interconnect region R, and extends to the dicing region D to electrically connect to the pad 12P. The interconnect 12W is routed in the dicing region D and electrically connects the metal layers 12M located in the respective interconnect regions R. That is, the pad 12P is electrically connected to the metal layer 12W located in each interconnect region R via the interconnect 12M.

Next, as illustrated in FIG. 4D, the insulating layers 13 and 23 and the interconnect layers 14 and 24 are formed. First, the insulating layer 13 is formed to cover the interconnect layer 12 including the metal layer 12M in each interconnect region R on the first surface 10a of the core layer 10 and to extend to the dicing region D. The insulating layer 13 covers the interconnect 12W and the pad 12P constituting the interconnect layer 12 in the dicing region D. For example, a film of a semi-cured epoxy-based resin or the like is laminated on each interconnect region R and the dicing region D of the first surface 10a of the core layer 10 to cover the interconnect layer 12, and the resin film is cured to form the insulating layer 13. Alternatively, instead of laminating the film of the epoxy-based resin or the like, a liquid or paste of an epoxy-based resin or the like may be coated on each interconnect region R and the dicing region D of the first surface 10a of the core layer 10 to cover the interconnect layer 12, and the resin liquid or paste may be cured to form the insulating layer 13. The material used for and the thickness of the insulating layer 13 are as described above. Similarly, the insulating layer 23 covering the interconnect layer 22 is laminated on each interconnect region R and the dicing region D of the second surface 10b of the core layer 10.

Next, the via hole 13x penetrating the insulating layer 13 and exposing the upper surface of the interconnect layer 12 is formed in the insulating layer 13 located in each interconnect region R. In addition, the via hole 13x penetrating the insulating layer 13 and exposing an upper surface of the pad 12P is formed in the insulating layer 13 located in the dicing region D. Moreover, the via hole 23x penetrating the insulating layer 23 and exposing the lower surface of the interconnect layer 22 is formed in the insulating layer 23 located in each interconnect region R. The via holes 13x and 23x can be formed by laser processing using a CO₂ laser or the like, for example. After forming the via holes 13x and 23x, it is preferable to perform a desmear process to remove resin residues adhered to the surfaces of the interconnect layers 12 and 22 exposed at bottoms of the via holes 13x and 23x, respectively.

Next, the interconnect layer 14 is formed on one side of the insulating layer 13. The interconnect layer 14 includes a pad 14P formed in the dicing region D. The interconnect layer 14 includes a via interconnect filling inside the via hole 13x, and an interconnect pattern or a pad formed on the upper surface of the insulating layer 13. The interconnect layer 14 located in each interconnect region R is electrically connected to the interconnect layer 12 exposed at the bottom of the via hole 13x. The pad 14P located in the dicing region D is electrically connected to the pad 12P exposed at the bottom of the via hole 13x. Similarly, the interconnect layer 24 is formed on the other side of the insulating layer 23. The interconnect layer 24 includes a via interconnect filling inside the via hole 23x, and an interconnect pattern formed on the lower surface of the insulating layer 23. The interconnect layer 24 is electrically connected to the interconnect layer 22 exposed at the bottom of the via hole 23x. A material used for and a thickness of the interconnect patterns of the interconnect layers 14 and 24 may be the same as those of the interconnect layer 12, for example. The interconnect layers 14 and 24 are formed using a semi-additive process, for example.

Next, as illustrated in FIG. 5A, the insulating layers 15 and 25, the interconnect layers 16 and 26, the solder resist layers 17 and 27, and the external connection terminals 18 are formed. The interconnect layer 16 includes a pad 16P formed in the dicing region D. First, the same process as that of FIG. 4D is repeated to form the insulating layers 15 and 25 and the interconnect layers 16 and 26. Next, the solder resist layer 17 is formed on the upper surface of the insulating layer 15 to cover the interconnect layer 16. In addition, the solder resist layer 27 is formed on the lower surface of the insulating layer 25 to cover the interconnect layer 26. The solder resist layer 17 may be formed by coating a liquid or paste of a photosensitive epoxy-based insulating resin on the upper surface of the insulating layer 15 by screen printing, roll coating, spin coating, or the like to cover the interconnect layer 16. Alternatively, the solder resist layer 17 may be formed by laminating a film of the photosensitive epoxy-based insulating resin on the upper surface of the insulating layer 15 to cover the interconnect layer 16. The method of forming the solder resist layer 27 is the same as that of forming the solder resist layer 17. Thereafter, the solder resist layers 17 and 27 are exposed and developed to form an opening 17x that exposes the interconnect layer 16 in the solder resist layer 17 located in each interconnect region R. In addition, an opening 17x exposing the pad 16P is formed in the solder resist layer 17 located in the dicing region D. Further, an opening 27x that exposes a portion of the lower surface of the interconnect layer 26 is formed in the solder resist layer 27. If necessary, the external connection terminal 18 may be provided on the interconnect layer 16 exposed inside the opening 17x located in each interconnect region R. The external connection terminal 18 is a solder bump formed by a solder reflow process or the like, for example. The pad 16P exposed inside the opening 17x is electrically connected to each metal layer 12M, and constitutes one conductive terminal exposed on the side of the upper surface 51a of the first stack 51 located in the dicing region D. That is, the pad 16P, which is a conductive terminal, is electrically connected to the metal layer 12M formed in each interconnect region R via the pad 14P, the pad 12P, and the interconnect 12W disposed in the dicing region D. The first stack 51 and the second stack 52 having the interconnect region R and the dicing region D are formed by the processes illustrated in FIG. 4B through FIG. 5A.

Next, in the process illustrated in FIG. 5B through FIG. 6C, a recess 51z that opens at the upper surface 51a of the first stack 51 is formed to span across a boundary between each interconnect region R and the dicing region D. The recess 51z is formed by a routing processing (counterbore machining) using a router bit, for example.

First, as illustrated in FIG. 5B and FIG. 5C, a cutting jig 300 including an electrical continuity jig 310, a conductive dicing tool 320, and a continuity detection device 330 for detecting electrical continuity of the electrical continuity jig 310 and dicing tool 320 is prepared. Further, the electrical continuity jig 310 is brought into contact with the pad 16P that becomes the conductive terminal. Because the electrical continuity jig 310 has a shape with a protrusion protruding toward the pad 16P, a stable electrical continuity can be ensured between the electrical continuity 310 and the pad 16P. The protrusion may have spring properties. In this case, it is possible to ensure a more stable electrical continuity between the electrical continuity jig 310 and the pad 16P. In addition, the electrical continuity jig 310 may have a shape with a plurality of protrusions protruding toward the pad 16P. In this case, it is possible to ensure an even more stable electrical continuity between the electrical continuity jig 310 and the pad 16P. Examples of the electrical continuity jig 310 include a metal jig made of copper, aluminum, iron, or the like, for example. Examples of the dicing tool 320 include a router bit made of a metal and having an approximate circular shape or the like in the plan view, for example. Examples of the continuity detection device 330 include an electronic device or the like including a central processing unit (CPU), for example.

Next, as illustrated in FIG. 6A, the dicing tool 320 is disposed at a position overlapping at least a portion of the metal layer 12M in the plan view. For example, the dicing tool 320 is disposed at a central portion of a region where the recess 51z is to be formed in the plan view. Then, the dicing tool 320 is rotated in a horizontal direction with a center in a longitudinal direction (a vertical direction in FIG. 6A) of the dicing tool 320 as a rotation axis of the dicing tool 320. Next, the rotating dicing tool 320 is lowered in a direction perpendicular to the first surface 10a of the core layer 10 while dicing the first stack 51, and the lowering is stopped at a time when the continuity detection device 330 detects the electrical continuity between the electrical continuity jig 310 and the dicing tool 320. Because the metal layer 12M and the pad 16P are electrically connected inside the first stack 51, the continuity detection device 330 detects the electrical continuity between the electrical continuity jig 310 and the dicing tool 320 at the time when the dicing tool 320 comes into contact with the metal layer 12M, and the lowering of the dicing tool 320 is stopped at the position where the dicing tool 320 is in contact with the metal layer 12M.

Next, as illustrated in FIG. 6B, in a state where the continuity detection device 330 detects the electrical continuity, the dicing tool 320 is moved in a direction parallel to the first surface 10a of the core layer 10, to form the recess 51z. For example, the dicing tool 320 is gradually moved from the central portion of the region where the recess 51z is to be formed to an outer periphery of the region where the recess 51z is to be formed in a rectangular spiral shape in the plan view, to form the recess 51z. The state where the continuity detection device 330 detects the electrical continuity refers to a state in which the dicing tool 320 is always in contact with the metal layer 12M. For example, when the metal layer 12M includes undulations or the like and there is no contact between the metal layer 12M and the dicing tool 320 even for a moment, the dicing tool 320 automatically moves downward toward the metal layer 12M to maintain contact with the metal layer 12M. When forming the recess 51z, the insulating layer 13 in the region where the recess 51z is to be formed is thinned to a thickness identical to the thicknesses of the metal layer 12M and the interconnect 12W. In addition, in the plan view, a distance from the side surface of the metal layer 12M on the side of the pad 16P to the inner wall surface of the recess 51z on the side of the pad 16P becomes less than or equal to a diameter of the dicing tool 320. FIG. 6C illustrates a cross section of the structure formed with the recess 51z. A portion of the upper surface 12a of the metal layer 12M is exposed at the bottom of the recess 51z.

Next, as illustrated in an upper part of FIG. 7, a blade 400 is lowered in a direction of an outlined arrow, and the structure formed with the recess 51z is diced at the boundary between the interconnect region R and the dicing region D to singulate the structure. Specifically, the first stack 51 located outside the recess 51z, the interconnect 12W and the insulating layer 13 located inside the recess 51z, the core layer 10, and the second stack 52 are diced and singulated into individual pieces. As a result, the interconnect region R and the dicing region D are separated from each other as illustrated in a lower part of FIG. 7, and a plurality of wiring boards 1 are completed. The recess 51x having the diced recess 51z is formed in each of the wiring board 1. The recess 51x opens to the upper surface 51a and the side surface 51c of the first stack 51. As an example, a rotary blade is used for the blade 400.

As described above, in the method for manufacturing the wiring board 1, when forming the recess 51z, the first stack 51 is diced using the dicing jig 300 until the upper surface 12a of the metal layer 12M becomes exposed, and the recess 51z can be formed while maintaining the contact between the dicing tool 320 and the metal layer 12M. That is, by detecting the electrical continuity of the dicing tool 320 and the metal layer 12M, the dicing tool 320 can be moved in the horizontal direction while controlling a dicing depth of the dicing tool 320, and thus, the recess 51z having a desired depth can be formed.

In the method for manufacturing the wiring board 1, the metal layer 12M is not diced during the singulation. Instead, the interconnect 12W narrower than the metal layer 12M is diced, so that burrs are less likely generated. That is, the wiring board 1 having a structure in which burrs are less likely generated on the side surface 12c of the metal layer 12M can be realized.

### Modifications of First Embodiment

In modifications of the first embodiment, examples of the wiring board having a shape different from that of the first embodiment will be described. In the modifications of the first embodiment, a description of the constituent elements or components that are the same as those of the embodiment described above may be omitted.

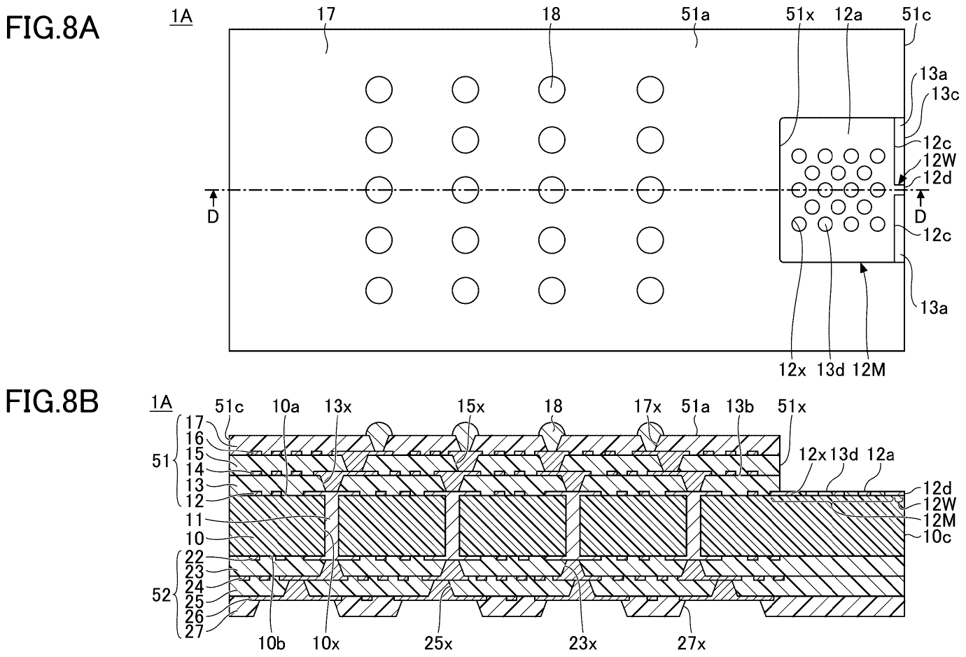

FIG. 8A and FIG. 8B are diagrams illustrating an example of the wiring board according to a first modification of the first embodiment. FIG. 8A is a plan view, and FIG. 8B is a cross sectional view taken along a line D-D in FIG. 8A. A wiring board 1A illustrated in FIG. 8A and FIG. 8B differs from the wiring board 1 in that a plurality of through holes is provided in the metal layer 12M, and a portion of the insulating layer 13 is located inside each through hole 12x of the metal layer 12M.

The through hole 12x has a circular shape in the plan view, for example, but the through hole 12x may have other shapes, such as a rectangular shape, a triangular shape, or the like in the plan view. An upper surface 13d of the insulating layer 13 located inside the through hole 12x lies on the same plane as the upper surface 12a of the metal layer 12M, for example. The through hole 12x can function as a gas vent hole (so-called degassing hole) for releasing a gas generated inside the wiring board 1A when heated during the manufacturing process of the wiring board 1A. By providing the through hole 12x, it is possible to suitably suppress the generation of voids inside the wiring board 1A. An arbitrary number of through holes 12x, which may be one or more, may be provided.

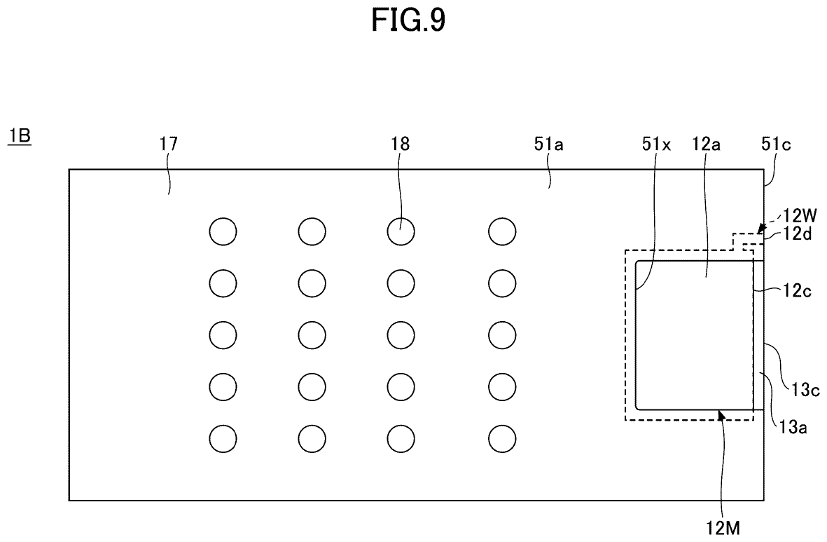

FIG. 9 is a plan view illustrating an example of the wiring board according to a second modification of the first embodiment. In a wiring board 1B illustrated in FIG. 9, similar to the wiring board 1, the side surface 12c of the metal layer 12M exposed at the bottom of the recess 51x is located closer to the center of the first stack 51 than to the side surface 51c of the first stack 51 in the plan view, and the side surface 12c of the metal layer 12M is covered with the insulating layer 13 exposed at the bottom of the recess 51x. In FIG. 9, portions of the interconnect 12W and the metal layer 12M covered with the first stack 51 (insulating layer 13) are indicated by broken lines.

The position of the interconnect 12W in the plan view of the wiring board 1B differs from that of the wiring board 1. Specifically, in the wiring board 1B, the upper surface of the interconnect 12W is covered with the insulating layer 13 and is not exposed inside the recess 51x. The interconnect 12W is connected to the side surface of the metal layer 12M not exposed inside the recess 51x, and is bent in the plan view so that the end surface 12d is exposed on the side of the side surface 10c of the core layer 10. In addition, the end surface 12d of the interconnect 12W is exposed on the side of the side surface 51c of the first stack 51. The end surface 12d of the interconnect 12W lies on the same plane as the side surface 10c of the core layer 10, for example. Further, the end surface 12d of the interconnect 12W lies on the same plane as the side surface 51c of the first stack 51, for example. The upper surface of the interconnect 12W lies on the same plane as the upper surface 12a of the metal layer 12M and the upper surface 13a of the insulating layer 13, for example.

Accordingly, the interconnect 12W may be provided so as not to be exposed inside the recess 51x. The interconnect 12W can be provided at an arbitrary position where the metal layer 12M and the pad 16P can be electrically connected before the wiring board 1B is singulated during the manufacturing process of the wiring board 1B.

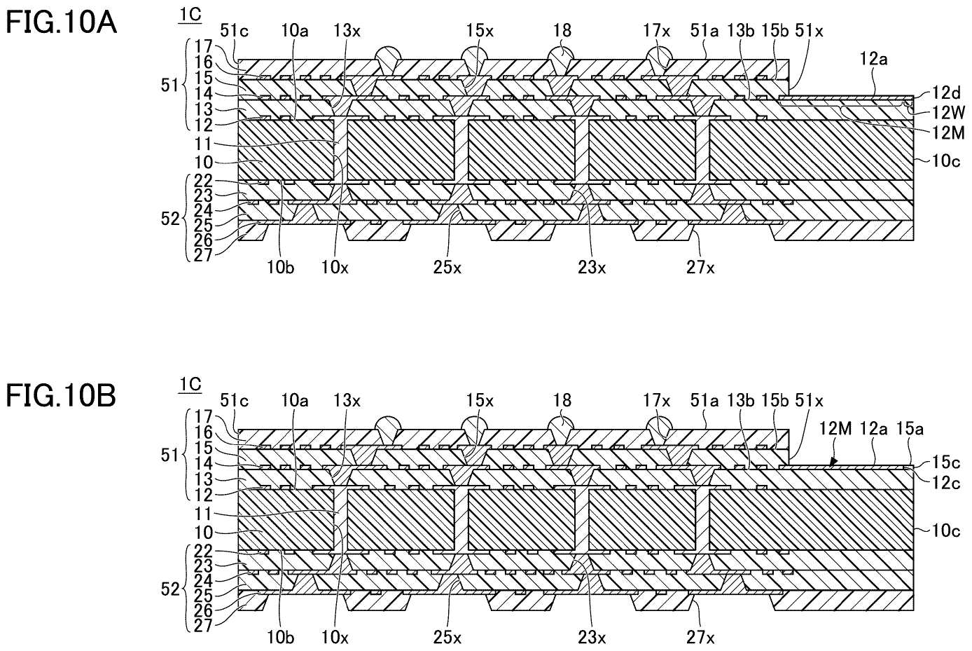

FIG. 10A and FIG. 10B are cross sectional views illustrating an example of the wiring board according to a third modification of the first embodiment., where FIG. 10A illustrates a cross section corresponding to FIG. 2A, and FIG. 10B illustrates a cross section corresponding to FIG. 2B. In a wiring board 1C illustrated in FIG. 10A and FIG. 10B, the position of the metal layer 12M constituting a portion of the bottom of the recess 51x differs from that of the wiring board 1. In the wiring board 1C, a depth of the recess 51x is shallower than that in the wiring board 1.

In the wiring board 1C, the metal layer 12M is provided on the upper surface 13b of the insulating layer 13 and constitutes a portion of the interconnect layer 14. A planar shape of the metal layer 12M is the same as that of the wiring board 1. The side surface 12c of the metal layer 12M exposed at the bottom of the recess 51x is located closer to the center of the first stack 51 than to the side surface 51c of the first stack 51 in the plan view, and the side surface 12c of the metal layer 12M is covered with the insulating layer 15 exposed at the bottom of the recess 51x.

An upper surface 15a of the insulating layer 15 exposed at the bottom of the recess 51x is located at a position lower than the upper surface 15b of the insulating layer 15 constituting the first stack 51. The upper surface 12a of the metal layer 12M lies on the same plane as the upper surface 15a of the insulating layer 15, for example. A side surface 15c of the insulating layer 15 exposed at the bottom of the recess 51x is exposed on the side of the side surface 10c of the core layer 10. In addition, the side surface 15c of the insulating layer 15 exposed at the bottom of the recess 51x is exposed on the side of the side surface 51c side of the first stack 51. The side surface 15c of the insulating layer 15 exposed at the bottom of the recess 51x lies on the same plane as the side surface 10c of the core layer 10, for example. The side surface 15c of the insulating layer 15 exposed at the bottom of the recess 51x lies on the same plane as the side surface 51c of the first stack 51, for example.

In the present embodiment, the interconnect 12W is exposed at the bottom of the recess 51x. The end surface 12d of the interconnect 12W is exposed on the side of the side surface 10c of the core layer 10. In addition, the end surface 12d of the interconnect 12W is exposed on the side of the side surface 51c of the first stack 51. The end surface 12d of the interconnect 12W lies on the same plane as the side surface 10c of the core layer 10, for example. The end surface 12d of the interconnect 12W lies on the same plane as the side surface 51c of the first stack 51, for example. The upper surface of the interconnect 12W lies on the same plane as the upper surface 12a of the metal layer 12M and the upper surface 15a of the insulating layer 15.

As described above, the metal layer 12M constituting a portion of the bottom of the recess 51x can be provided in the same layer as any one of the interconnect layers constituting the first stack 51. In other words, the metal layer 12M may be provided on the first surface 10a of the core layer 10, or may be provided on an upper surface of an arbitrary insulating layer located above the core layer 10. The depth of the recess 51x can be adjusted by varying the layer on which the metal layer side 12M is provided.

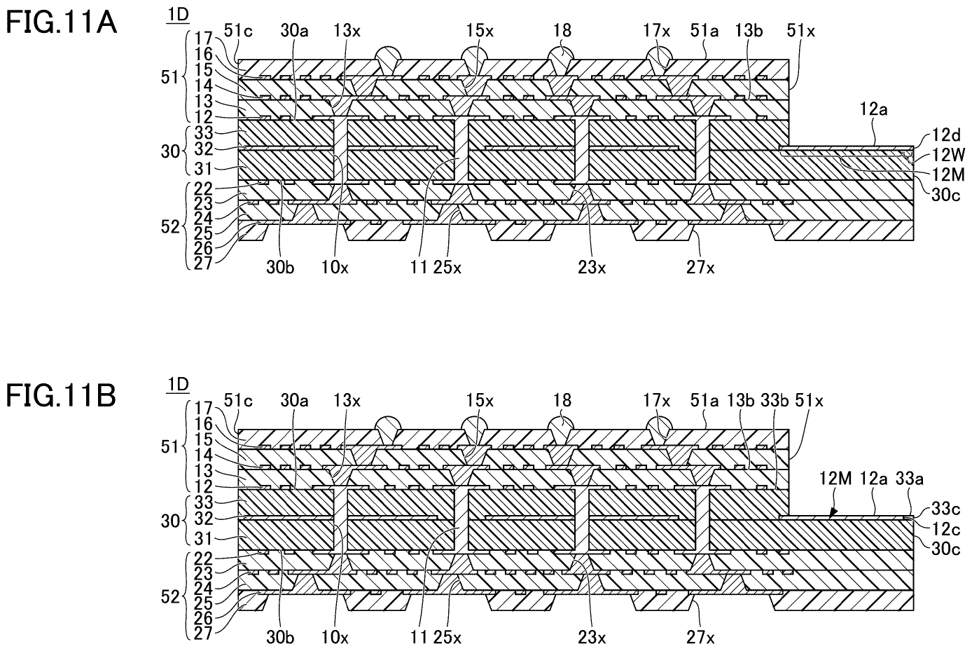

FIG. 11A and FIG. 11B are cross sectional views illustrating an example of the wiring board according to a fourth modification of the first embodiment. FIG. 11A illustrates a cross section corresponding to FIG. 2A, and FIG. 11B illustrates a cross section corresponding to FIG. 2B. In a wiring board 1D illustrated in FIG. 11A and FIG. 11B, the position of the metal layer 12M constituting a portion of the bottom of the recess 51x differs from that of the wiring board 1. In the wiring board 1D, the depth of the recess 51x is deeper than that in the wiring board 1.

The wiring board 1D has a core layer 30 in place of the core layer 10, and the first stack 51 is formed on a first surface 30a of the core layer 30, and a second stack 52 is formed on a second surface 30b opposite from the first surface 30a of the core layer 30. The core layer 30 has a multilayer structure including an insulating layer 31, an interconnect layer 32 disposed on an upper surface of the insulating layer 31, and an insulating layer 33 that is stacked on the upper surface of the insulating layer 31 and covers the interconnect layer 32. A material used for the insulating layers 31 and 33 may be the same as that of the core layer 10, for example. The insulating layer 31 and the insulating layer 33 may have the same thickness or may have mutually different thicknesses.

In the wiring board 1D, the metal layer 12M is provided on the upper surface of the insulating layer 31, and constitutes a portion of the interconnect layer 32. The planar shape of the metal layer 12M is the same as that of the wiring board 1. The recess 51x penetrates the solder resist layer 17, the insulating layer 15, and the insulating layer 13. In addition, the recess 51x is formed to a portion of the insulating layer 33. The upper surface 12a of the metal layer 12M is exposed at the bottom of the recess 51x. The side surface 12c of the metal layer 12M exposed at the bottom of the recess 51x is located closer to the center of the first stack 51 than to the side surface 51c of the first stack 51 in the plan view, and the side surface 12c of the metal layer 12M is covered with the insulating layer 33 exposed at the bottom of the recess 51x.

An upper surface 33a of the insulating layer 33 exposed at the bottom of the recess 51x is located at a position lower than an upper surface 33b of the insulating layer 33 constituting the core layer 30. The upper surface 12a of the metal layer 12M lies on the same plane as the upper surface 33a of the insulating layer 33, for example. A side surface 33c of the insulating layer 33 exposed at the bottom of the recess 51x is exposed on the side of the side surface 30c the core layer 30. In addition, the side surface 33c of the insulating layer 33 exposed at the bottom of the recess 51x is exposed on the side of the side surface 51c of the first stack 51. The side surface 33c of the insulating layer 33 exposed at the bottom of the recess 51x lies on the same plane as the side surface 30c of the core layer 30, for example. The side surface 33c of the insulating layer 33 exposed at the bottom of the recess 51x lies on the same plane as the side surface 51c of the first stack 51, for example.

In the present embodiment, the interconnect 12W is exposed at the bottom of the recess 51x. The end surface 12d of the interconnect 12W is exposed on the side of the side surface 30c of the core layer 30. The end surface 12d of the interconnect 12W is exposed on the side of the side surface 51c of the first stack 51. The end surface 12d of the interconnect 12W lies on the same plane as the side surface 30c of the core layer 30, for example. The end surface 12d of the interconnect 12W lies on the same plane as the side surface 51c of the first stack 51, for example. The upper surface of the interconnect 12W lies on the same plane as the upper surface 12a of the metal layer 12M and the upper surface 33a of the insulating layer 33.

As described above, the core layer 30 has a multilayer structure including the interconnect layer 32, and thus, the metal layer 12M constituting a portion of the bottom of the recess 51x can be provided in the same layer as the interconnect layer 32 constituting the core layer 30. Hence, it is possible to make the depth of the recess 51x deeper than that in the wiring board 1. Further, the depth of the recess 51x can be adjusted by varying the thickness of the insulating layer 33.

When manufacturing the wiring board 1D, a via hole penetrating the insulating layer 33 and exposing the upper surface of the pad 12P is formed in the dicing region D of the core layer 30, and a pad extending from the inside of the via hole to the upper surface 33b of the insulating layer 33 is formed. Then, the pad 14P and the pad 16P are sequentially stacked on the pad extending from the inside of the via hole. Hence, the interconnect 12W can be electrically connected to the pad 16P, and thus, the recess 51z can be formed while controlling the dicing depth of the dicing tool 320.

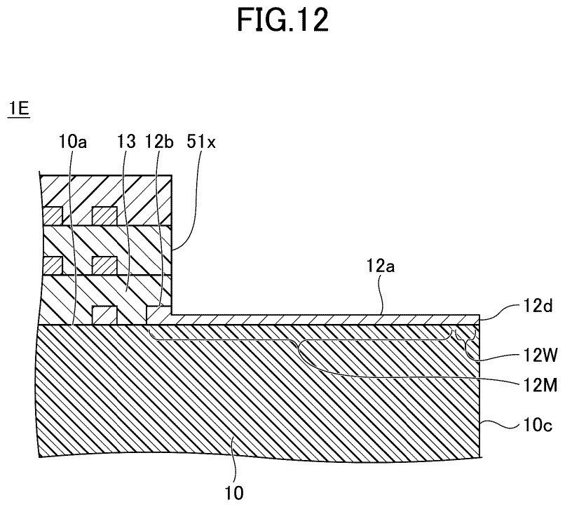

FIG. 12 is a partial cross sectional view illustrating an example of the wiring board according to a fifth modification of the first embodiment. FIG. 12 illustrates a part of a cross section corresponding to FIG. 2A on an enlarged scale. A wiring board 1E illustrated in FIG. 12 differs from the wiring board 1 in that the thickness of the metal layer 12M and the interconnect 12W exposed at the bottom of the recess 51x is smaller than the thickness of a portion of the metal layer 12M covered with the insulating layer 13. Otherwise, the configuration of the wiring board 1E is the same as that the wiring board 1.

In the wiring board 1E, when the first surface 10a of the core layer 10 is taken as a reference, the upper surface 12a of the metal layer 12M exposed at the bottom of the recess 51x is located at a position lower than the upper surface 12b of a portion of the metal layer 12M covered with the insulating layer 13. In addition, the upper surface of the interconnect 12W exposed at the bottom of the recess 51x is located at a position lower than the upper surface 12b of a portion of the metal layer 12M covered with the insulating layer 13. The upper surface of the interconnect 12W exposed at the bottom of the recess 51x is located at a position lower than the upper surface of a portion of the interconnect 12W covered with the insulating layer 13 and disposed in the dicing region D during the manufacturing process of the wiring board 1E.

The structure of the wiring board 1E described above can be formed by removing a portion of the surface of the metal layer 12M and a portion of the surface of the interconnect 12W when performing the dicing process for forming the recess 51z during the manufacturing process of the wiring board 1E. Alternatively, as illustrated in FIG. 6C, after forming the recess 51z, the metal layer 12M and the interconnect 12W exposed at the bottom of the recess 51z may be etched to remove a portion of the surface of the metal layer 12M and a portion of the surface of the interconnect 12W exposed at the bottom of the recess 51z.

Accordingly, resin residues of the insulating layer 13 are prevented from being generated on the upper surface 12a of the metal layer 12M, which serves as the bottom surface of the recess 51x. Hence, it is possible to suitably mount a component, such as an optical fiber array or the like, on the upper surface 12a of the metal layer 12M.

### Second Embodiment

Next, a second embodiment will be described. The second embodiment relates to an example of the optical module in which an optical waveguide device or the like is mounted on the wiring board according to the first embodiment. In the second embodiment, a description of the constituent elements or components that are the same as those of the embodiment described above may be omitted.

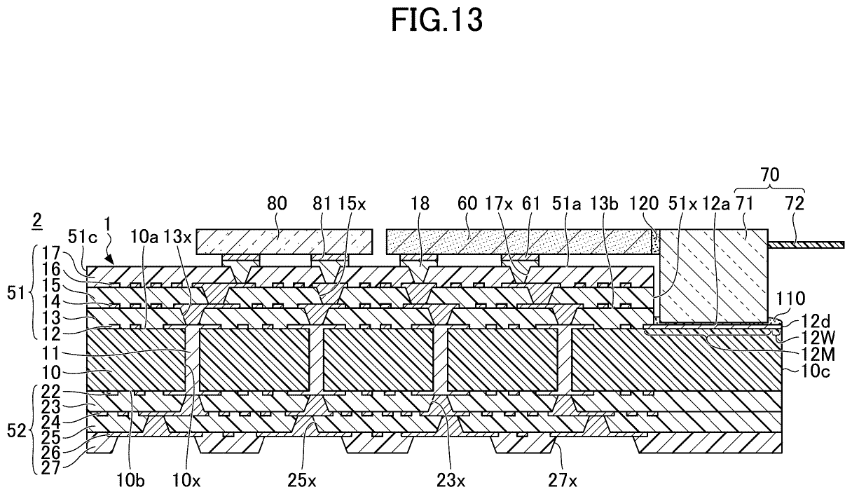

FIG. 13 is a cross sectional view illustrating an example of the optical module according to the second embodiment. As illustrated in FIG. 13, an optical module 2 includes the wiring board 1 illustrated in FIG. 1, an optical waveguide device 60, an optical fiber array 70, and an electronic component 80. The optical module 2 may include two or more optical waveguide devices 60.

The optical waveguide device 60 is a silicon photonics component, for example. The optical waveguide device 60 includes one or more optical devices and one or more optical waveguides, for example. The optical device is a light emitting element or a light receiving element, for example. The optical waveguide is a silicon optical waveguide, for example. The optical waveguide device 60 converts an electrical signal from the electronic component 80 into an optical signal and transmits the optical signal to the optical fiber array 70, or converts an optical signal from the optical fiber array 70 into an electrical signal and transmits the electrical signal to the electronic component 80. The optical waveguide device 60 includes a photoelectric conversion device.

The optical waveguide device 60 is mounted on the upper surface 51a of the first stack 51 of the wiring board 1. The optical waveguide device 60 can be flip-chip mounted on the upper surface 51a of the first stack 51, for example. Specifically, a lower surface of the optical waveguide device 60 is provided with a plurality of electrode pads 61, and the electrode pads 61 are electrically connected to a portion of the interconnect layer 16 constituting the first stack 51 via the external connection terminals 18. The electrode pad 61 is a metal post, for example. The electrode pad 61 may be made of copper or a copper alloy, for example.

The optical fiber array 70 includes a housing 71, and one or more optical fibers 72. The housing 71 holds the one or more optical fibers 72. The optical fiber 72 has a core through which the optical signal propagates, and a cladding that surrounds an outer periphery of the core.

The optical fiber array 70 is disposed inside the recess 51x to face an end surface of the optical waveguide device 60. Specifically, the optical fiber array 70 is arranged so that a center axis of the core of the optical fibers 72 matches a center axis of a core of the optical waveguide of the optical waveguide device 60. That is, the optical fiber array 70 is arranged so that the optical axes of the cores of the optical fibers 72 match the optical axes of the cores of the optical waveguides of the optical waveguide device 60. The housing 71 constituting the optical fiber array 70 is fixed to the upper surface 12a of the metal layer 12M by an adhesive 110, for example. For example, an ultraviolet curable adhesive or a thermosetting adhesive can be used for the adhesive 110. A side surface of the housing 71 may or may not be in contact with the inner wall surface of the recess 51x.

An optical adhesive 120 is disposed between the opposing surfaces of the optical fiber array 70 and the optical waveguide device 60. The optical fibers 72 of the optical fiber array 70 are optically coupled to the optical waveguides of the optical waveguide device 60 by the optical adhesive 120. The optical adhesive 120 may be disposed so as to fill a gap or space between the optical waveguide device 60 and the optical fiber array 70, for example. By filling the optical adhesive 120 in the gap or space between the optical waveguide device 60 and the optical fiber array 70, it becomes possible to prevent air reflection and increase a coupling efficiency between the optical waveguides of the optical waveguide device 60 and the optical fibers 72. For example, an ultraviolet curable optical adhesive can be used for the optical adhesive 120. An optical adhesive having a refractive index close to a refractive index of the core of the optical waveguide 64 or a refractive index of the core of the optical fiber 72 is preferably used for the optical adhesive 120.

The electronic component 80 is an integrated circuit (IC) chip, such as a driver that drives the optical device of the optical waveguide device 60 or the like, for example. Specifically, the electronic component 80 may be an IC chip embedded with a digital signal processor (DSP), an amplifier, or the like for processing an output signal from the optical waveguide device 60, for example.

The electronic component 80 is mounted on the upper surface 51a of the first stack 51 of the wiring board 1. The electronic component 80 can be flip-chip mounted on the upper surface 51a of the first stack 51, for example. Specifically, a lower surface of the electronic component 80 is provided with a plurality of electrode pads 81, and the electrode pads 81 are electrically connected to a portion of the interconnect layer 16 constituting the first stack 51 via the external connection terminals 18. The electrode pad 81 is a metal post, for example. The electrode pad 81 may be made of copper or a copper alloy, for example.

In the optical module 2, the optical fiber array 70 to be connected to the optical waveguide device 60 is fixed to the metal layer 12M constituting the bottom surface of the recess 51x. For this reason, the optical fiber array 70 is bonded to the optical waveguide device 60 and is also bonded on the core layer 10. For this reason, it is possible to improve a bonding strength of the optical fiber array 70 with respect to the optical waveguide device 60 and the core layer 10, compared to a case where the optical fiber array 70 is bonded only to the optical waveguide device 60. In other words, the bonding strength between the optical waveguide device 60 and the optical fiber array 70 can be improved by bonding the optical fiber array 70 on the core layer 10. As a result, a connection reliability between the optical waveguide device 60 and the optical fiber array 70 can be improved. For example, even when an external force is unintentionally applied to the optical fiber array 70, it is possible to suitably prevent unwanted disconnection between the optical waveguide device 60 and the optical fiber array 70.

Further, because the optical fiber array 70 is fixed to the metal layer 12M constituting the bottom surface of the recess 51x, the position of the optical axis of the optical fiber 72 in the thickness direction of the first stack 51 can easily be adjusted by adjusting the depth of the recess 51x. Hence, it is possible to suitably match the optical axis of the optical fiber 72 to the optical axis of the optical waveguide of the optical waveguide device 60.

According to the disclosed technique, it is possible to provide a wiring board having the structure designed to minimize burrs on the side surface of the metal layer exposed at the bottom of the recess.

Various aspects of the subject-matter described herein may be set out non-exhaustively in the following numbered clauses:
1. A method for manufacturing a wiring board, comprising:
   forming a stack having an interconnect region to be singulated into a wiring board and a dicing region to be diced when singulating the stack into the wiring board;
   forming a recess that opens at an upper surface of the stack to span a boundary between the interconnect region and the dicing region; and
   dicing a structure formed with the recess at the boundary to singulate the structure, wherein:
   the forming the stack includes forming, in the dicing region, a metal layer not reaching the dicing region, and forming an insulating layer covering the metal layer, and
   the forming of the recess includes dicing the stack with a conductive dicing tool until an upper surface of the metal layer is exposed, and adjusting a dicing depth of the dicing tool by detecting an electrical continuity between the dicing tool and the metal layer.
2. The method for manufacturing the wiring board according to clause 1, wherein:
   the forming the stack includes forming a conductive terminal electrically connected to the metal layer and exposed at the upper surface of the stack located in the dicing region, and
   the forming of the recess includes:
      preparing a dicing jig including an electrical continuity jig and a continuity detection device configured to detect an electrical continuity between the electrical continuity jig and the dicing tool, and bringing the electrical continuity jig into contact with the conductive terminal;
      lowering the dicing tool while dicing the stack, and stopping the lowering at a point in time when the continuity detection device detects the electrical continuity; and
      moving the dicing tool in a direction parallel to the upper surface of the stack to form the recess in a state where the continuity detection device detects the electrical continuity.
3. The method for manufacturing the wiring board according to clause 2, wherein:
   the forming the stack includes forming the stack having a plurality of interconnect regions,
   the forming the metal layer forms the metal layer in each interconnect region of the plurality of interconnect regions,
the forming the conductive terminal forms one conductive terminal electrically connected to the metal layer formed in each interconnect region of the plurality of interconnect regions via an interconnect disposed in the dicing region.

Although the embodiments are numbered with, for example, “first,” or “second,” the ordinal numbers do not imply priorities of the embodiments, and the same applies to the modifications numbered with ordinal numbers. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

For example, in the embodiments described above, the wiring board has the first stack on one surface of the core layer and the second stack on the other surface of the core layer. However, the present disclosure can be applied to a wiring board having the first stack on one surface of the core layer and not having the second stack on the other surface of the core layer, and in this case, it is possible to obtain the same effects as those obtainable when both the first stack and the second stack are provided. In a case where the wiring board does not have the second stack, the through hole does not need to be provided in the core layer. The present disclosure is also applicable to a coreless substrate in which the core layer is omitted. In this case, the coreless substrate can be formed of only the first stack, for example.

What is claimed is:

1. A wiring board comprising:
a stack;
a recess that opens at an upper surface and a side surface of the stack;
a metal layer having an upper surface exposed at a bottom of the recess; and
an insulating layer having an upper surface exposed at the bottom of the recess,
wherein a side surface of the metal layer is covered with the insulating layer.

2. The wiring board as claimed in claim 1, wherein the upper surface of the metal layer lies on the same plane as the upper surface of the insulating layer.

3. The wiring board as claimed in claim 1, wherein a side surface of the insulating layer is exposed at the side surface side of the stack.

4. The wiring board as claimed in claim 3, wherein the side surface of the insulating layer lies on the same plane as the side surface of the stack.

5. The wiring board as claimed in claim 1, further comprising:
an interconnect electrically connected to the metal layer and having an end surface exposed at the side surface of the stack.

6. The wiring board as claimed in claim 5, wherein the end surface of the interconnect lies on the same plane as the side surface of the stack.

7. The wiring board as claimed in claim 5, wherein the interconnect is provided on the same layer as the metal layer, and is exposed at the bottom of the recess.

8. The wiring board as claimed in claim 1, wherein:
the metal layer has a through hole,
a portion of the insulating layer is located inside the through hole, and
the upper surface of the insulating layer located inside the through hole lies on the same plane as the upper surface of the metal layer.

9. The wiring board as claimed in claim 1, wherein the upper surface of the metal layer is a component mounting surface.
